(19) United States
(12) Patent Application Publication
(10) Pub. No.: US 2017/0362965 A1
(43) Pub. Date: Dec. 21, 2017

(54) BORON DOPED TA-C COATING FOR ENGINE COMPONENTS

(71) Applicant: Federal-Mogul LLC, Southfield, MI (US)

(72) Inventors: Robert Reuven Aharonov, West Bloomfield, MI (US); Troy Kantola, Whitmore, MI (US)

(21) Appl. No.: 15/185,698

(22) Filed: Jun. 17, 2016

(51) Int. Cl. F01L 1/14; F16C 3/06; C23C 16/27; F16J 9/26; C23C 14/22

(52) U.S. Cl. CPC F01L 1/14; F16J 9/26; C23C 14/221; C23C 16/27; F16C 3/06

(57) ABSTRACT

An engine component, for example a piston ring, including a wear resistant coating applied by physical vapor deposition (PVD) is provided. The coating includes tetrahedral amorphous carbon (ta-C), the carbon of the coating includes sp³ hybrid orbitals, and the coating includes boron in an amount of 0.1 wt. % to 4.0 wt. %, based on the total weight of the coating. The doped boron makes the coating less sensitive to the ion energy during the physical vapor deposition (PVD) process, improves adhesion of the coating, and expected to reduce compressive stress in the coating. Thus, the boron-doped ta-C coating can be applied to a greater thickness compared to ta-C coatings without the doped boron. In addition, there is a strong indication that the addition of boron will maintain a high level of sp³ bonded carbon and a high microhardness.

### BACKGROUND OF THE INVENTION

### 1. Field of the Invention

The invention relates generally to components for internal combustion engines, such as coated piston rings, and methods of forming the same.

### 2. Related Art

Components for a reciprocating engine, such as an internal combustion engines, are subjected to high wear and thus are oftentimes coated to prolong service life. For example, a piston of the internal combustion engine typically includes piston rings disposed in grooves along the outer diameter of the piston. The piston rings facilitate guiding of the piston during reciprocation in a cylinder bore. The piston rings also seal combustion gases and inhibit the upward passage of oil. However, the piston rings are subject to wear as they move along the cylinder bore due to gas load and their own inherent load. Accordingly, the outer diameter surfaces of the piston rings are coated or treated to enhance wear resistance. For example, the piston rings may be nitrided, coated with chromium, or coated with a ceramic, which may be applied by physical vapor deposition (PVD) or chemical vapor deposition (CVD).

### SUMMARY OF THE INVENTION

One aspect of the invention provides a component for an engine, for example a piston ring, which is coated to enhance wear resistance. The component includes a base body presenting an outer surface, and the coating is applied to the outer surface of the base body. The coating includes tetrahedral amorphous carbon (ta-C), and the carbon of the coating includes sp³ hybrid orbitals. The coating further includes boron in an amount of 0.1 wt. % to 4.0 wt. %, based on the total weight of the coating.

Another aspect of the invention provides a method of manufacturing a coated component for an engine, for example a piston ring. The method includes applying a coating to an outer surface of a base body. The coating includes tetrahedral amorphous carbon (ta-C), the carbon of the coating includes sp³ hybrid orbitals, and the coating includes boron in an amount of 0.1 wt. % to 4.0 wt. %, based on the total weight of the coating.

The doped boron makes the coating less sensitive to ion energy and improves adhesion of the coating to the component. In addition, the doped boron is expected to reduce compressive stress in the coating, which typically limits the thickness of ta-C coatings. Thus, the boron-doped ta-C coating can be applied to a greater thickness compared to ta-C coatings without the doped boron. The improved adhesion and greater thickness of the coating will increase the service life of the coated component. In addition, there is a strong indication that the addition of boron in the amount of 0.1 wt. % to 4.0 wt. % will allow the coating to maintain a high level of sp³ bonded carbon and a high microhardness, without an unacceptable amount of internal or compressive stress.

### BRIEF DESCRIPTION OF THE DRAWINGS

Other advantages of the present invention will be readily appreciated, as the same becomes better understood by reference to the following detailed description when considered in connection with the accompanying drawings, wherein:

FIG. 1 is a perspective view of a coated piston ring according to an embodiment of the invention; and

FIG. 2 is an enlarged cross-sectional view of a portion of the coated piston ring of FIG. 1.

### DETAILED DESCRIPTION OF EXAMPLE EMBODIMENTS

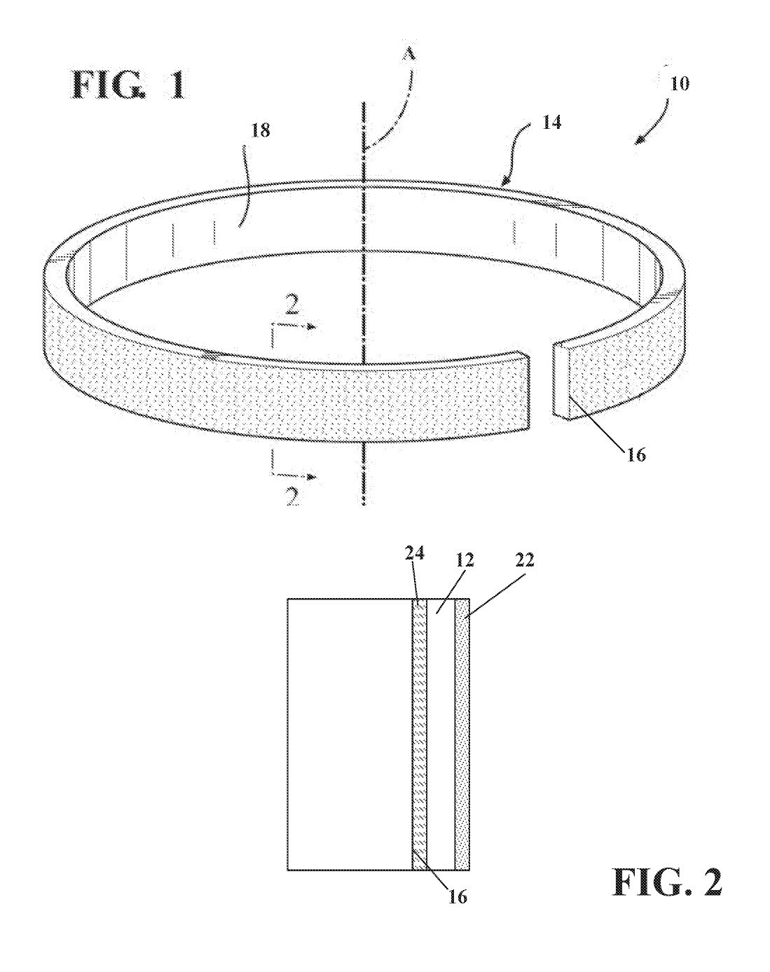

One aspect of the invention provides a coated component, for example a piston ring 10, for reciprocating engine applications, such as internal combustion engines. Alternatively, the component could be another component of the engine which is subject to wear, such as a piston pin, crank shaft, tappet, etc. A coating 12 including tetrahedral amorphous carbon (ta-C) is applied to the piston ring 10 to improve wear resistance. An example of the coated piston ring 10 is shown in FIGS. 1 and 2.

The piston ring 10 includes a base body 14 extending circumferentially around a center axis A. The base body 14 is formed of a metal material, such as cast iron, steel, or cast steel. The base body 14 presents an outer surface 16 facing opposite the center axis A and an inner surface 18 facing and surrounding the center axis A.

The coating 12 is applied to the outer surface 16 of the base body 14, which slides along the inner surface of a cylinder liner (not shown) during use in the internal combustion engine. Thus, the coating 12 prevents wear caused by the friction between the piston ring 10 and cylinder liner. The coating 12 includes diamond-like carbon (DLC), and thus is referred to as a DLC coating.

More specifically, the coating 12 applied to the base body 14 is homogenous and includes tetrahedral amorphous carbon (ta-C). The ta-C is also known as the toughest form of diamond-like carbon. The carbon of the coating 12 includes a mixture of carbon including sp² hybrid orbitals and carbon including sp³ hybrid orbitals. The ratio of sp² to sp³ hybrid orbitals present in the coating 12 ranges from 1:99 to 99:1. The amount of sp² and sp³ hybrid orbitals depends on the desired properties of the coating 12. The sp³ hybrid orbitals increase the hardness of the coating 12 but also increase the compressive or internal stress of the coating 12. According to one embodiment, greater than 50% of the carbon atoms present in the coating 12 include sp³ hybrid orbitals, for example 50% to 99%, or 65% to 90%, or 70% to 85% of the hybrid orbitals can be sp³ hybrid orbitals. The carbon atoms including sp³ hybrid orbitals are bonded to other carbon atoms including sp³ hybrid orbitals. The coating 12 is also free of hydrogen.

In the example embodiment, the coating 12 is applied to the base body 14 of the piston ring 10 by physical vapor deposition (PVD). This process typically includes forming a cathode comprising a mixture, and applying a gas including positive ions to the cathode so that the mixture of the cathode deposits on the outer surface 16 and forms the coating 12.

The coating 12 applied to the base body 14 also includes boron in an amount of 0.1 wt. % to 4.0 wt. %, based on the total weight of the coating. In one example embodiment, boron particles are mixed with graphite or carbon particles to form the cathode, and the cathode is then subjected to the ion energy of the physical vapor deposition process such that the mixture of the cathode deposits on the outer surface 16 of the base body 14 and forms the coating 12. In another example embodiment, the cathode is formed of graphite powder, and the boron is provided in the gas to form the coating 12. Alternatively, some of the boron can be provided in the solid cathode, and some can be provided in the gas to form the coating 12.

The boron makes the coating 12 less sensitive to the ion energy during the physical vapor deposition process and improves adhesion of the coating 12 to the outer surface 16 of the piston ring 10. In addition, the doped boron is expected to reduce compressive or internal stress in the coating 12, which typically limits the thickness of ta-C coatings. Thus, the boron-doped ta-C coating 12 can be applied to a greater thickness compared to ta-C coatings without the doped boron. The improved adhesion and greater thickness of the coating 12 will increase the service life of the coated piston ring 10. In addition, there is a strong indication that the addition of boron in the amount of 0.1 wt. % to 4.0 wt. % will allow the coating 12 to maintain a high level of sp³ bonded carbon and a high microhardness, with an acceptable level of internal or compressive stress and thickness.

In the example embodiment, the thickness of the coating 12 is greater than the thickness of other known ta-C coatings without doped boron. For example, the coating 12 can have a thickness of 1 to 60 microns. The coating 12 also maintains a high microhardness, due to the sp³ hybrid orbitals. The coating 12 also has a friction coefficient which contributes to the improved wear resistance, for example a friction coefficient of 0.01 to 0.30.

Optionally, the piston ring 10 can include an adhesive layer 24 disposed between the outer surface 16 and the coating 12, and/or a finish layer 22 applied to the coating 12. The adhesive layer 24 is typically a metal layer, for example a layer formed of chromium, titanium, chrome nitride, or another hard material or compound. The outermost surface of the piston ring 10 can be formed by the finish layer 22, when present, or by the wear resistant coating 12, when the finish layer 22 not present.

Another aspect of the invention provides a method of manufacturing the coated piston ring 10. The method includes applying the coating 12 to the outer surface 16 of a base body 14. As discussed above, the coating 12 includes tetrahedral amorphous carbon (ta-C), the carbon of the coating 12 includes sp³ hybrid orbitals, and the coating 12 includes boron in an amount of 0.1 wt. % to 4.0 wt. %, based on the total weight of the coating 12.

In the example embodiment, the step of applying the coating 12 to the outer surface 16 of the base body 14 includes physical vapor deposition (PVD). Various different types of physical vapor deposition can be used, but in the example embodiment, the physical vapor deposition step includes a plasma-assisted high vacuum process. Other methods that can be used to apply the coating 12 include laser arc vapor deposition, magnetically enhanced arc vapor deposition, filtered arc vapor deposition, and magnetron sputtering, or another process capable of re-condensing the mixture of tetrahedral amorphous carbon (ta-C) and boron on the base body 14. In the example embodiment, the process includes forming a cathode by mixing carbon or graphite and the boron particles in an amount of 0.1 wt. % to 4.0 wt. %, based on the total weight of the mixture, and the step of applying the coating 12 to the outer surface 16 includes applying a gas including positive ions to the cathode so that the mixture of the cathode deposits on the outer surface 16 and forms the coating 12. Alternatively, the boron can be provided in the gas used to form the coating 12, or some of the boron can be provided in the cathode, and some of the boron can be applied in the gas. The gas typically includes argon, and argon ions of plasma atomize or vaporize the mixture and cause the mixture to deposit on the outer surface 16 of the base body 14. In the example embodiment, the coating 12 is applied to a thickness of 1 to 60 microns.

As discussed above, according to the example embodiment, the carbon of the coating 12 is diamond-like carbon (DLC). The coating 12 is also homogeneous and free of hydrogen. The carbon of the coating 12, which includes the sp³ hybrid orbitals, is in the form of atoms including sp³ hybrid orbitals bonded one another.

The method can optionally include applying the adhesive layer 24 to the outer surface 16 of the base body 14 prior to applying the coating 12. The adhesive layer 24 is typically a metal layer, for example a layer formed of chromium, titanium, chrome nitride, or another hard material or compound. The method can also optionally include applying the finish layer 22 to the coating 12.

Obviously, many modifications and variations of the present invention are possible in light of the above teachings and may be practiced otherwise than as specifically described while within the scope of the following claims.

1. A component for an engine, comprising:
a base body presenting an outer surface,
a coating applied to said outer surface of said base body,
said coating including tetrahedral amorphous carbon (ta-C), the carbon of said coating including sp^{a} hybrid orbitals,
said coating including boron in an amount of 0.1 wt. % to 4.0 wt. %, based on the total weight of said coating.

2. The component of claim 1, wherein said component is a piston ring, piston pin, crank shaft, or tappet.

3. The component of claim 2, wherein said base body of said piston ring presents an inner surface surrounding a center axis, said base body presents said outer surface facing opposite said center axis, said base body is formed of a metal material, and said metal material is cast iron, steel, or cast steel.

4. The component of claim 1, wherein the carbon of said coating is diamond-like carbon (DLC).

5. The component of claim 1, wherein said coating is homogenous.

6. The component of claim 1, wherein the coating includes a ratio of sp² hybrid orbitals to sp^{a} hybrid orbitals ranging from 1:99 to 99:1.

7. The component of claim 1, wherein greater than 50% of the carbon present in said coating includes the sp³ hybrid orbitals.

8. The component of claim 1, wherein the carbon of the coating comprises carbon atoms including sp³ hybrid orbitals bonded to other carbon atoms including sp³ hybrid orbitals.

9. The component of claim 1, wherein said coating is free of hydrogen,

10. The component of claim 1, wherein said coating has a thickness of 1 to 60 microns and a friction coefficient of 0.01 to 0.30.

11. The component of claim 1, wherein an adhesive layer is disposed between said outer surface and said coating, and a finish layer is applied to said coating.

12. The component of claim 1, wherein said component is a piston ring,
said base body of said piston ring presents an inner surface surrounding a center axis,
said base body presents said outer surface facing opposite said center axis,
said base body is formed of a metal material, said metal material is cast iron, steel, or cast steel,
the carbon of said coating is diamond-like carbon (DLC),
said coating is homogenous,
said coating includes a ratio of sp² hybrid orbitals to sp³ hybrid orbitals ranging from 1:99 to 99:1;
the carbon of said coating comprises carbon atoms comprising sp³ hybrid orbitals bonded to other carbon atoms including sp³ hybrid orbitals,
said coating is free of hydrogen,
said coating has a thickness of 1 to 60 microns, and
said coating has a friction coefficient of 0.01 to 0.30.

13. A method of manufacturing a component for an engine, comprising:
applying a coating to an outer surface of a base body, the coating including tetrahedral amorphous carbon (ta-C), the carbon of the coating including sp³ hybrid orbitals, and the coating including boron in an amount of 0.1 wt. % to 4.0 wt. %, based on the total weight of the coating.

14. The method of claim 13, wherein the step of applying the coating to the outer surface includes physical vapor deposition.

15. The method of claim 14, wherein the physical vapor deposition step includes at least one of plasma-assisted high vacuum process, laser arc vapor deposition, magnetically enhanced arc vapor deposition, filtered arc vapor deposition, and magnetron sputtering.

16. The method of claim 13 including forming a cathode by mixing particles of carbon or graphite and particles of the boron in an amount of 0.1 wt. % to 4.0 wt. %, based on the total weight of the mixture, and
wherein the step of applying the coating to the outer surface includes applying a gas including positive ions to the cathode so that the mixture of the cathode deposits on the outer surface and forms the coating.

17. The method of claim 13 including forming a cathode of graphite, and wherein the step of applying the coating to the outer surface includes applying a gas including positive ions and boron to the cathode so that the tetrahedral amorphous carbon (ta-C) and the boron deposits on the outer surface and forms the coating.

18. The method of claim 13, wherein the component is a piston ring, piston pin, crank shaft, or tappet.

19. The component of claim 13, wherein the carbon of the coating comprises carbon atoms including sp³ hybrid orbitals bonded to other carbon atoms including sp³ hybrid orbitals.

20. The method of claim 13, wherein said component is a piston ring,
the base body of the piston ring presents an inner surface surrounding a center axis,
the base body presents the outer surface facing opposite the center axis,
the base body is formed of a metal material, the metal material is cast iron, steel, or cast steel,
the carbon of the coating is diamond-like carbon (DLC),
the coating is homogenous,
the coating includes a ratio of sp² hybrid orbitals to sp³ hybrid orbitals ranging from 1:99 to 99:1;
the carbon of the coating comprises carbon atoms comprising sp³ hybrid orbitals bonded to other carbon atoms including sp³ hybrid orbitals,
the coating is free of hydrogen,
the coating has a thickness of 1 to 60 microns, and
the coating has a friction coefficient of 0.01 to 0.30.
